(19) United States
(12) Patent Application Publication
(10) Pub. No.: US 2026/0066588 A1
(43) Pub. Date: Mar. 5, 2026

(54) CONNECTOR ASSEMBLY

(71) Applicant: Molex, LLC, Lisle, IL (US)

(72) Inventor: Che-Yuan Yang, New Taipei City (TW)

(21) Appl. No.: 19/294,353

(22) Filed: Aug. 8, 2025

(30) Foreign Application Priority Data
Sep. 5, 2024 (CN) 202411240112.4

(51) Int. Cl. H01R 13/6581; H01R 13/502; H01R 13/627; H05K 7/20

(52) U.S. Cl. CPC H01R 13/6581; H01R 13/502; H01R 13/6272; H05K 7/20409

(57) ABSTRACT

A connector assembly includes a guide shielding cage and a heat sink module, the guide shielding cage has an inserting passageway, the heat sink module is provided to the guide shielding cage and includes a heat sink and an actuating member, the heat sink has a base and a fin portion provided to the base, the actuating member has a shaft portion and a lever connecting the shaft portion, the lever has a first end portion and a second end portion which are connected with each other, the shaft portion passes through the heat sink and sits on a top surface of the base or the shaft portion passes through the heat sink and is at least partially positioned outside an air passageway; wherein the actuating member is normally in a first state and is capable of being displaced to a second state when the actuating member is subjected to a force; when the actuating member is in the first state, the first end portion enters into the inserting passageway; when the actuating member is in the second state, the second end portion of the actuating member acts on the heat sink to make the base of the heat sink enter into the inserting passageway.

### TECHNICAL FIELD

The present disclosure relates to a connector assembly, and particularly relates to a connector assembly which has a heat sink.

### BACKGROUND

Chinese patent document CN114623722A discloses a connector assembly, the connector assembly includes a guide shielding cage and a heat sink module, and the heat sink module includes a lever and a heat dissipating member, the lever may be pushed to apply a force to the heat dissipating member, in turn the heat dissipating member contacts a pluggable module, an effect of dissipating heat from the pluggable module is attained.

In such a connector assembly, because a provided position of the lever is on heat dissipating fins, it may be further considered to promote heat dissipating efficacy of the heat dissipating member while maintain the lever to be still capable of functioning.

### SUMMARY

Therefore, an object of the present disclosure is to provide a connector assembly which can improve at least one deficiency of the prior art.

Accordingly, a connector assembly of the present disclosure comprises a guide shielding cage and a heat sink module, the guide shielding cage has an inserting passageway, the heat sink module is provided to the guide shielding cage and comprises a heat sink and an actuating member, the heat sink has a base and a fin portion provided to the base, the actuating member has a shaft portion and a lever connecting the shaft portion, the lever has a first end portion and a second end portion which are connected with each other, the shaft portion passes through the heat sink and sits on a top surface of the base; wherein the actuating member is normally in a first state and is capable of being displaced to a second state when the actuating member is subjected to a force; when the actuating member is in the first state, the first end portion enters into the inserting passageway; when the actuating member is in the second state, the second end portion of the actuating member acts on the heat sink to make the base of the heat sink enter into the inserting passageway.

In some embodiments, the heat sink module further comprises a supporting elastic member, the supporting elastic member elastically supports the heat sink to make the actuating member normally in the first state.

In some embodiments, the base is formed with a first recessed groove, the fin portion is formed with a second recessed groove, the first recessed groove and the second recessed groove cooperate with each other to define a shaft hole which allows the shaft portion of the actuating member to pass therethrough, the shaft portion sits on a surface of the first recessed groove.

In some embodiments, the base comprises a plate portion and a thermal engaging portion, the thermal engaging portion is positioned to a bottom surface of the plate portion of the base, when the actuating member is in the second state, the second end portion presses down the plate portion.

In some embodiments, the base further comprises two side fins which extend upwardly from the plate portion, the fin portion is positioned between the two side fins.

In some embodiments, when the actuating member is in the second state, the second end portion is in a direction which is substantially parallel to the plate portion and the second end portion is close to the plate portion.

In some embodiments, the heat sink module further comprises a shell, the heat sink is received in the shell, the actuating member is provided to the shell.

In some embodiments, the shell comprises a lower shell and an upper shell which are engaged with each other, the supporting elastic member is formed to the lower shell of the shell.

In some embodiments, the lower shell of the shell is formed with a frame mouth, the two supporting elastic members are integrally constructed to the lower shell in a manner that the two supporting elastic members are respectively positioned to two sides of the frame mouth of the lower shell.

In some embodiments, the thermal engaging portion of the heat sink comprises a thermal conductive pad.

A connector assembly of the present disclosure comprises a guide shielding cage and a heat sink module, the guide shielding cage has an inserting passageway, the heat sink module is provided to the guide shielding cage and comprises a heat sink and an actuating member, the heat sink has a fin portion, the fin portion is formed with an air passageway, the actuating member has a shaft portion and a lever connecting the shaft portion, the lever has a first end portion and a second end portion, the shaft portion passing through the heat sink and is at least partially positioned outside the air passageway; wherein the actuating member is normally in a first state and is capable of being displaced to a second state when the actuating member is subjected to a force; when the actuating member is in the first state, the first end portion enters into the inserting passageway; when the actuating member is in the second state, the second end portion of the actuating member acts on the heat sink to make the heat sink enter into the inserting passageway.

A beneficial effect of the present disclosure lies in that, by adjustment of the provided position of the actuating member, the components of the heat sink module are more simplified, in addition, by that the shaft portion of the actuating member sits on the top surface of the base or is at least partially positioned outside the air passageway, blocking the air passageway of the fin portion is reduced, in turn influence on heat dissipating of the air flow of the air passageway due to blocking of the shaft portion is lowered.

### BRIEF DESCRIPTION OF THE DRAWINGS

Other features and effects of the present disclosure will be apparent from an embodiment with reference to the drawings, in which:

FIG. 1 is a perspective view of an embodiment of a connector assembly of the present disclosure illustrating that the connector assembly includes a guide shielding cage and a heat sink module with a pluggable module shown;

FIG. 2 is an exploded perspective view of the embodiment illustrating a positional relationship between the guide shielding cage and the heat sink module;

FIG. 3 is an exploded perspective view of the embodiment illustrating that the heat sink module includes a heat sink and an actuating member and the heat sink includes a base and a fin portion;

FIG. 4 is a perspective view of some components of the embodiment illustrating a state that the actuating member is provided to the fin portion;

FIG. 5 is a perspective view of some components of the embodiment illustrating a state that the actuating member is provided to the base;

FIG. 6 is a front view of the embodiment illustrating that a shaft portion of a lever passes through the heat sink and is at least partially positioned outside air passageways;

FIG. 7 is a cross-sectional view of the embodiment illustrating that the actuating member is in a first state; and

FIG. 8 is a cross-sectional view of the embodiment illustrating that the actuating member is in a second state.

### DETAILED DESCRIPTION

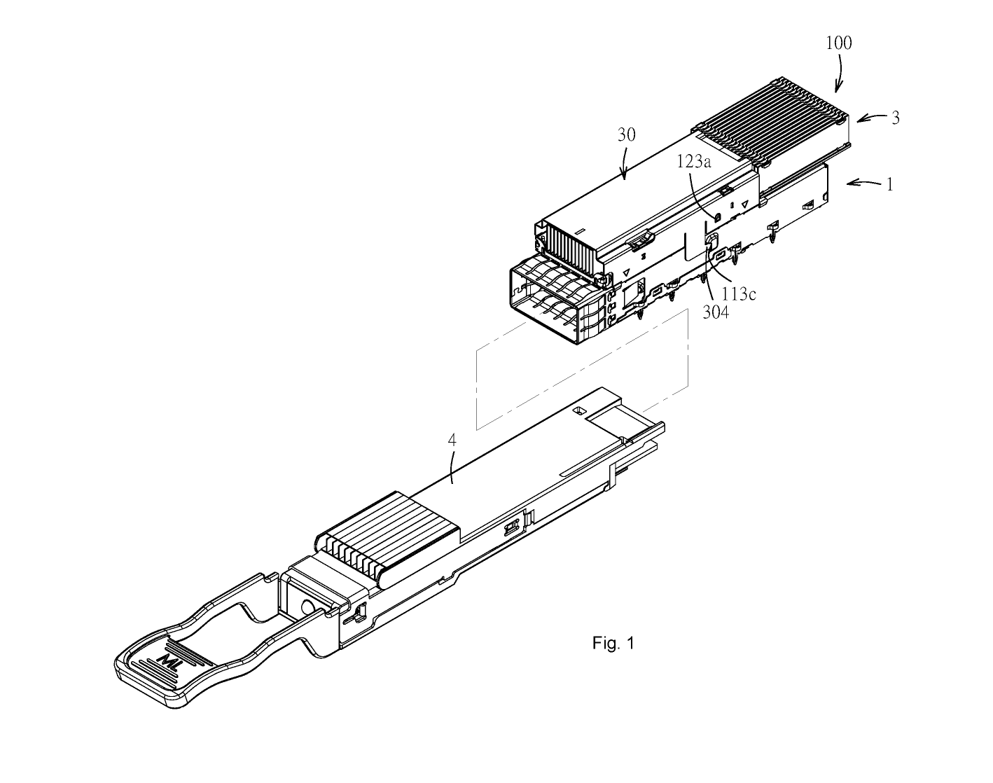

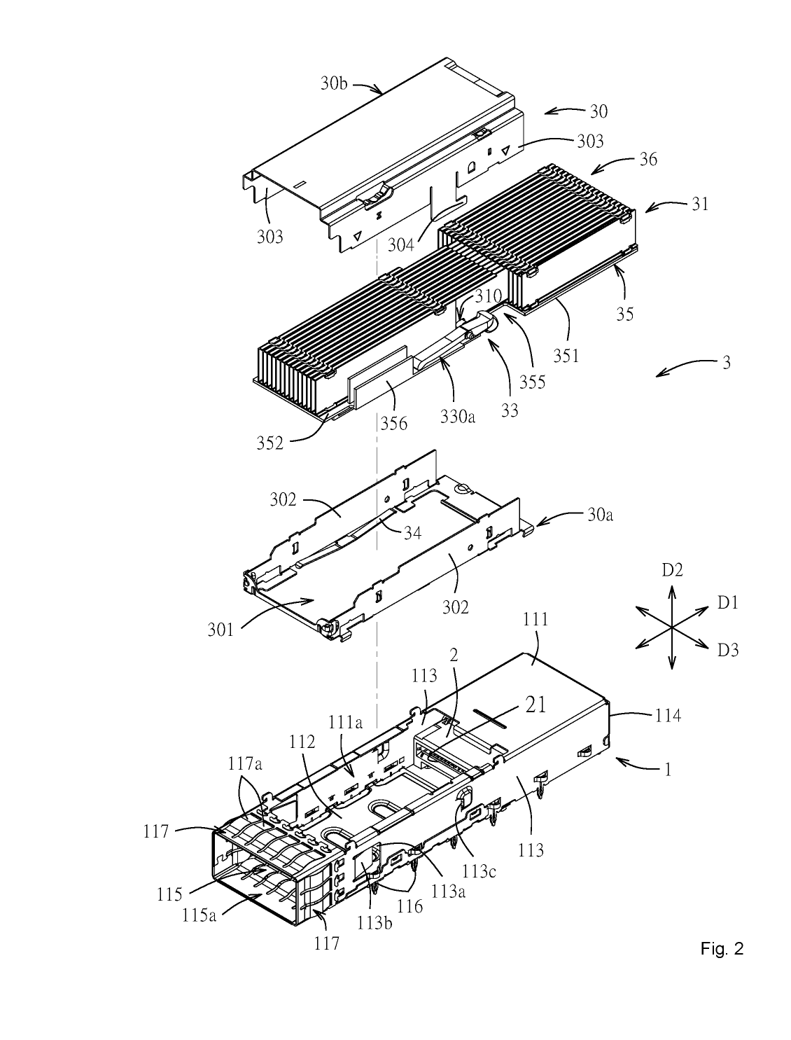

Referring to FIG. 1 and FIG. 2, an embodiment of a connector assembly100 of the present disclosure is adapted to mate with a pluggable module 4. The connector assembly 100 includes a guide shielding cage 1, a receptacle connector 2, and a heat sink module 3.

The guide shielding cage 1 has an inserting passageway 115 which allows the pluggable module 4 to insert therein. For example, the guide shielding cage 1 is formed by processing, such as, stamping and bending, a metal sheet with a mold. The guide shielding cage 1 may be provided to a circuit board (not shown) in a casing (not shown) and extend along a front-rear direction D1. In the present embodiment, the guide shielding cage 1 has a top wall 111, a bottom wall 112 which is spaced apart from the top wall 111 along an up-down direction D2, two side walls 113 which are spaced apart from each other along a left-right direction D3 and are connected between the top wall 111 and the bottom wall 112, a rear wall 114 which is connected to a rear edge of the top wall 111 and rear edges of the two side walls 113, the inserting passageway 115 which is defined together by the top wall 111, the bottom wall 112, the two side walls 113 and the rear wall 114, a plurality of inserting legs 116 which extend downwardly from the two side walls 113 and the rear wall 114 and are adapted to be fixed on the circuit board and/or be connected to a grounding trace (not shown), and a plurality of grounding members 117.

The inserting passageway 115 has an insertion opening 115a which is toward the front. The receptacle connector 2 is provided close to the rear wall 114 of the guide shielding cage 1 and makes a slot 21 of the receptacle connector 2 toward the front to allow the pluggable module 4 which inserts into the inserting passageway 115 to insert therein.

The top wall 111 has a window 111a which is communicated with the inserting passageway 115. Each side wall 113 has an opening 113a which is communicated with the inserting passageway 115 and is formed by stamping, an inward extending piece 113b which extends obliquely from a front edge of the opening 113a toward an interior of the guide shielding cage 1 and toward the rear, and an insertion hole 113c which is positioned behind the opening 113a and is opened toward the front, the inward extending piece 113b provides latching and position-limiting for the pluggable module 4 when the pluggable module 4 inserts into the inserting passageway 115. Each grounding member 117 has multiple elastic fingers 117a which extend rearwardly from a front end of the guide shielding cage 1 and are distributed to an outer side of the guide shielding cage 1 and an inner side of the guide shielding cage 1, the elastic finger 117a of the multiple elastic fingers 117a which is positioned to the outer side of the guide shielding cage 1 is used to contact an edge of a mounting hole of the casing, and the elastic finger 117a of the multiple elastic fingers 117a which is positioned to the inner side of the guide shielding cage 1 is used to contact the pluggable module 4.

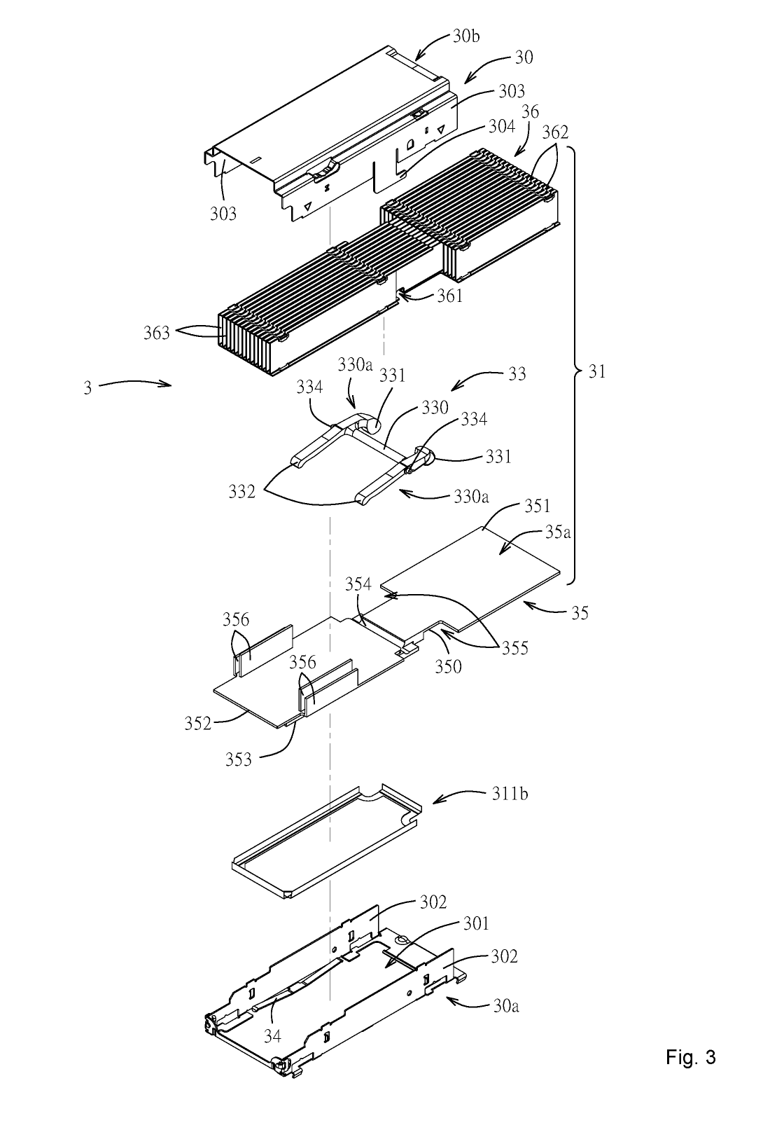

Referring to FIG. 1 to FIG. 3, the heat sink module 3 is mounted to the top wall 111 of the guide shielding cage 1 and corresponds to the inserting passageway 115. The heat sink module 3 includes a shell 30, a heat sink 31, an actuating member 33, and two supporting elastic members 34 (only one of the two supporting elastic members 34 is shown in FIG. 2 and FIG. 3 due to a viewing angle). The shell 30 includes a lower the shell 30a and an upper the shell 30b which are engaged with each other. The lower the shell 30a is substantially frame-shaped and includes two first side walls 302 which are positioned left and right respectively and define a frame mouth 301. In the present embodiment, the two supporting elastic members 34 each are in form of elastic piece, are integrally formed, are respectively connected to bottom edges of the two first side walls 302 of the lower the shell 30a, and are positioned in the frame mouth 301. Each supporting elastic member 34 is connected to the bottom edge of the corresponding first side wall 302 at a position which is between two ends of the supporting elastic member 34, the two ends of each supporting elastic member 34 is slightly oblique upwardly to be used to support corresponding one of a left side and a right side of a bottom of the heat sink 31. In other implementing manners, the supporting elastic member 34 also may be an independent component and may be engaged with the lower the shell 30a of the shell 30 by welding or latching.

A longitudinal cross section of the upper the shell 30b is substantially inverted U-shaped and includes two second side walls 303. Each second side wall 303 is formed with a hook 304 which extends downwardly and rearwardly. When the lower the shell 30a and the upper the shell 30b are engaged with each other and are provided to the top wall 111 of the guide shielding cage 1, the two first side walls 302 and the two second side walls 303 overlap with each other respectively, and the hooks 304 of the two second side walls 303 of the upper the shell 30b respectively insert into the two insertion holes 113c of the guide shielding cage 1, and the frame mouth 301 of the lower the shell 30a is correspondingly communicated with the window 111a of the top wall 111 of the guide shielding cage 1.

The heat sink 31 is received in the shell 30 and has a base 35 and a fin portion 36 provided to the base 35. In the present embodiment, the base 35 is formed with a first recessed groove 354 which extends along the left-right direction D3, the fin portion 36 is formed with a second recessed groove 361 which extends along the left-right direction D3, the first recessed groove 354 and the second recessed groove 361 cooperate with each other to define a shaft hole 310, whose function will be described below. In the present embodiment, the base 35 includes a plate portion 35a, a thermal engaging portion 353, and side fins 356 which extend upwardly from the plate portion 35a and are spaced apart from each other left and right. In the present embodiment, the plate portion 35a includes a first plate portion 351 and a second plate portion 352 which are connected with each other, the side fins 356 extend upwardly from the second plate portion 352 and are spaced apart from each other left and right, the first plate portion 351 is positioned at a rear of the plate portion 35a and the second plate portion 352 is positioned in the front of the plate portion 35a, the thermal engaging portion 353 is positioned to a bottom surface of the second plate portion 352 of the base 35. In the present embodiment, the base 35 further includes a connecting plate portion 350 which connects the first plate portion 351 and the second plate portion 352, and a width of the connecting plate portion 350 in the left-right direction D3 is less than a width of the first plate portion 351 and a width of the second plate portion 352, so that a left side and a right side of the connecting plate portion 350 each are formed with a notch 355, the first recessed groove 354 is a region which is substantially formed in the connecting plate portion 350. In the present embodiment, the fin portion 36 includes but is not limited to a plurality of heat dissipating fins 362 which latch with each other, and the plurality of heat dissipating fins 362 therebetween define a plurality of air passageways 363 which each extend along the front-rear direction D1, the air passageway 363 allows external air flow to enter into the fin portion 36 of the heat sink module 3 and flow from front to rear, and in turn take away heat energy which is conducted upwardly from the pluggable module 4 to the fin portion 36, a part of the fin portion 36 which is positioned in the second plate portion 352 is interposed between the side fins 356 which are positioned left and right. Moreover, provision of the side fins 356 is similarly helpful heat dissipating of the entire heat sink 31.

A provided position of the base 35 is to make the thermal engaging portion 353 correspond to the frame mouth 301 of the lower the shell 30a, so that thermal engaging portion 353 can pass through the frame mouth 301 and the window 111a of the guide shielding cage 1 to contact the pluggable module 4 which inserts into the inserting passageway 115, and perform heat dissipating on the pluggable module 4. In the present embodiment, the thermal engaging portion 353 includes a thermal conductive pad 311b which is positioned to a bottom of the thermal engaging portion 353 and is used to contact the pluggable module 4. For example, the thermal conductive pad 311b may be a thermal interface material, the thermal interface material may be selected from, for example, a combination of materials with performances, such as high thermal conductivity, high flexibility, compressibility, insulation, abrasion resistance, etc. al, and for example, can be a combination of a substrate material and a phase change material.

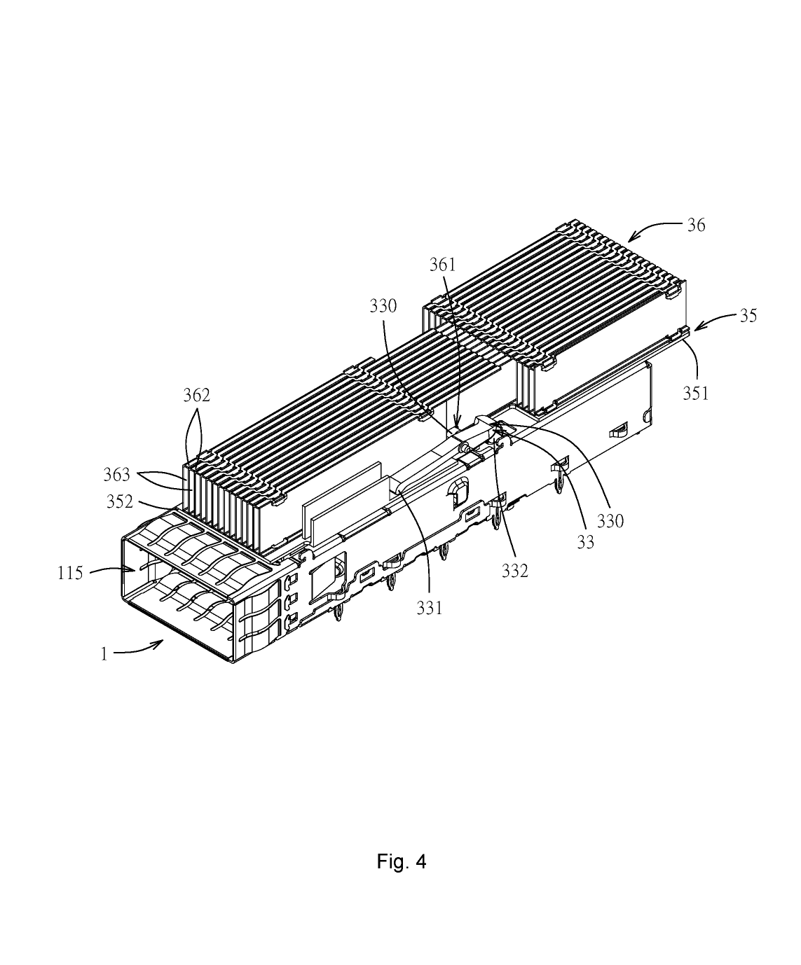

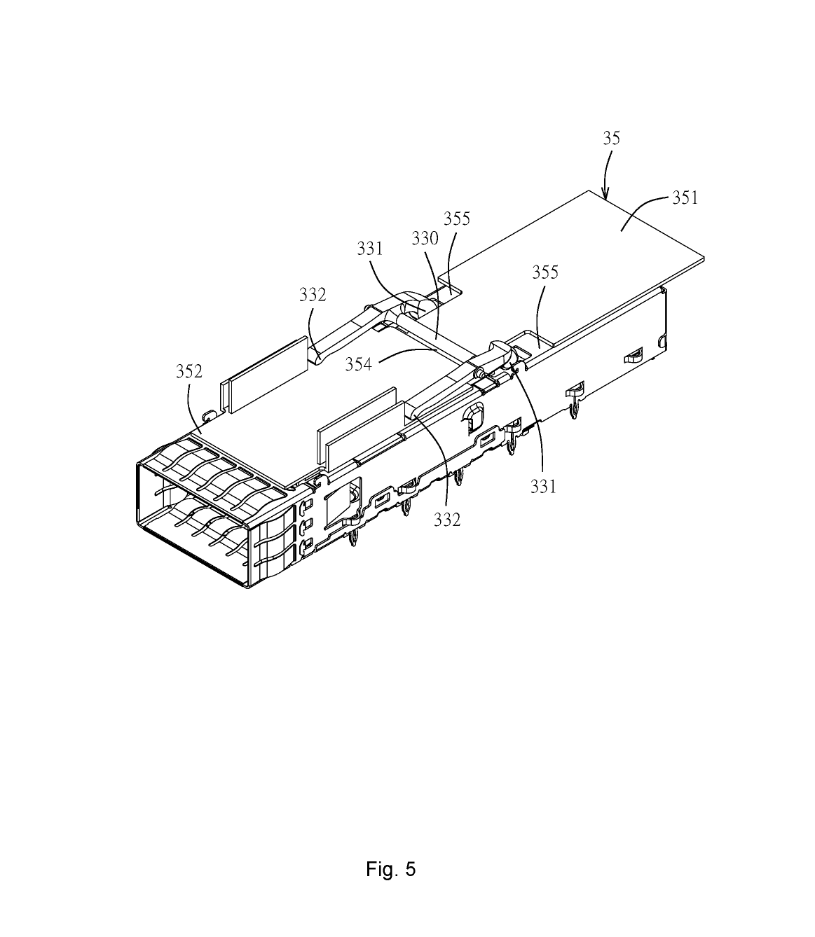

Referring to FIG. 3 to FIG. 6, the actuating member 33 is provided to be interposed between the first plate portion 351 and the second plate portion 352 of the base 35. A structure of the actuating member 33 is substantially H-shaped and has a shaft portion 330 and two levers 330a connecting the shaft portion 330. The shaft portion 330 is in form of rod shape which extends along the left-right direction D3, the two levers 330a each are provided along the front-rear direction D1 and the two levers 330a are spaced apart from each other left and right and are respectively connected to two ends of the shaft portion 330. Each lever 330a is substantially in form of strip and has a first end portion 331 which extends rearwardly and downwardly from the shaft portion 330 and a second end portion 332 which extends forwardly from the shaft portion 330.

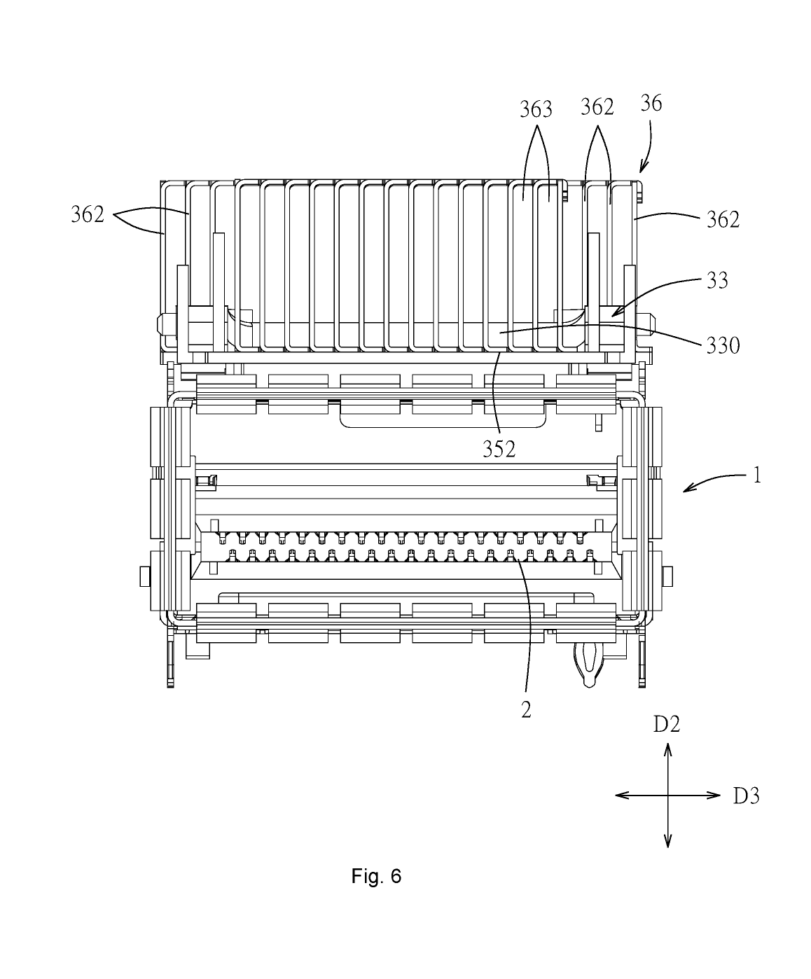

When the actuating member 33 is provided to the heat sink 31, the shaft portion 330 of the actuating member 33 passes through the shaft hole 310 which is defined by the first recessed groove 354 and the second recessed groove 361 of the heat sink 31 and sits on a top surface of the base 35, in other words, a position of the shaft portion 330 also may be understood that the shaft portion 330 is positioned to a bottom of the fin portion 36 and is at least partially positioned outside the air passageways 363, a position of the first end portion 331 is positioned in a region where the notch 355 is located, the second end portion 332 is positioned on the second plate portion 352 of the base 35. The actuating member 33 is entirely close to the base 35, an extent, that the actuating member 33 is entirely close to the base 35, as much as possible reduces that the shaft portion 330 of the actuating member 33 will block a region where the air passageways 363 of the heat dissipating fins 362 are present, thus, that the shaft portion 330 is at least partially positioned outside the air passageway 363 refers to that at least a part of the shaft portion 330 is positioned outside the region where the air passageways 363 of the heat dissipating fins 362 are present. For example, in the present embodiment, because the base 35 is formed with the first recessed groove 354, the top surface of the base 35 refer to an inner surface, which is recessed, of the first recessed groove 354, so, as shown in FIG. 6, a part of a height of the shaft portion 330 is positioned in the first recessed groove 354 rather than in the regions where the air passageways 363 are present, which thus may reduce a height of the shaft portion 330 which is positioned in the air passageways 363, in turn reduce the height of the shaft portion 330 which blocks the air passageways 363, lower influence on heat dissipating of air flows in the air passageways 363 due to blocking of the shaft portion 330, therefore, in a range that an entire thickness of the base 35 is considered at the same time, deeper a recessed depth of the first recessed groove 354 is, to the more extent influence on heat dissipating of the air flows in the air passageways 363 due to blocking of the shaft portion 330 may be lowered.

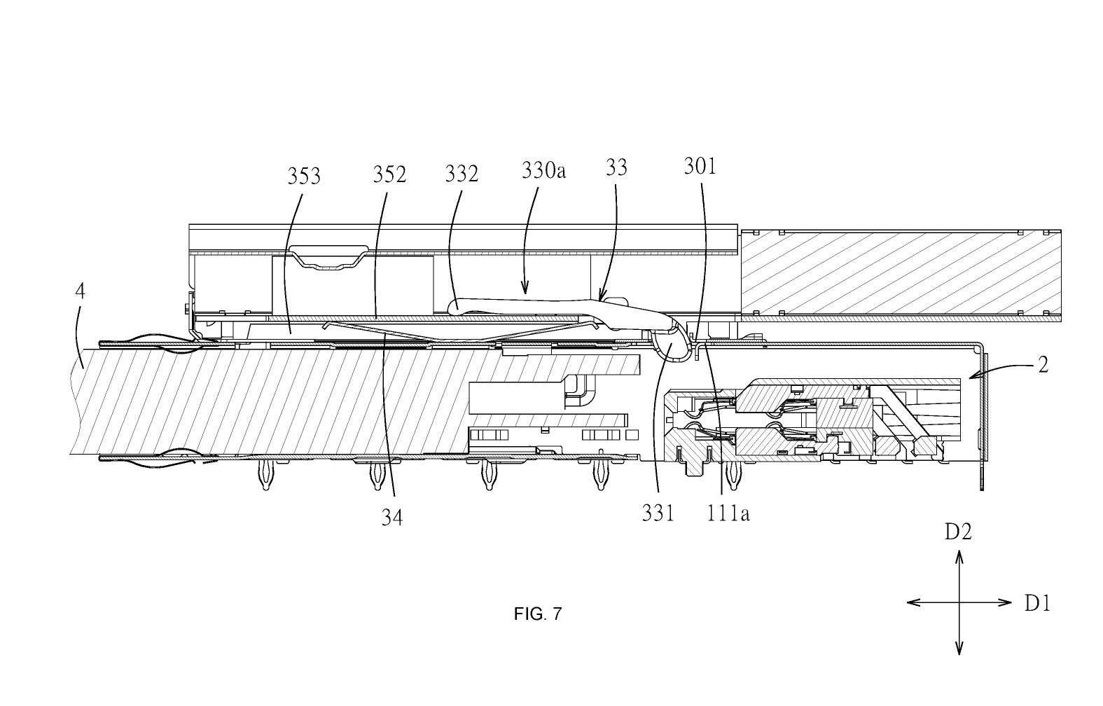

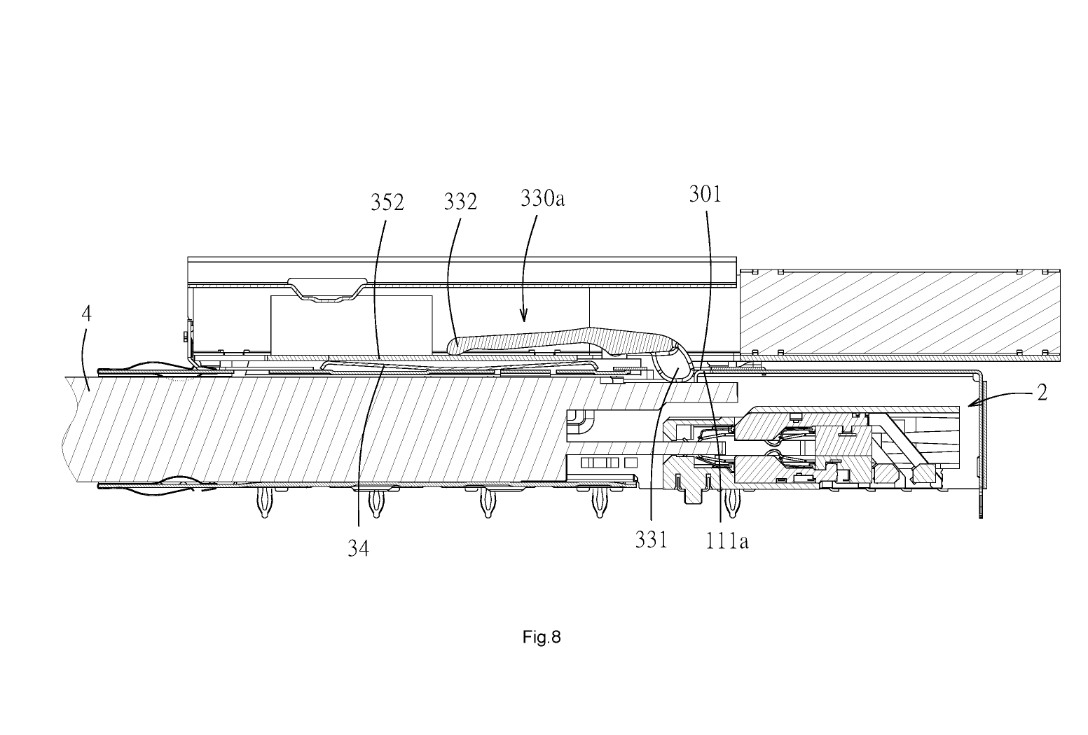

In the present embodiment, the actuating member 33 further has two pivoting shafts 334 which protrude from outer sides of the two levers 330a respectively, the two pivoting shafts 334 are pivoted to pivoting holes 123a which are respectively positioned in a left side and a right side of the shell 12 (see FIG. 1), therefore the actuating member 33 is capable of rotating between a first state (see FIG. 7) and a second state (see FIG. 8). It is noted that, in a varied implementing manner, the actuating member 33 of the heat sink module 3 also may only have one lever 330a. The two first end portions 331 are used to sequentially pass through the frame mouth 301 of the shell 30 and the window 111a of the guide shielding cage 1 to enter into the inserting passageway 115. Tips of the two second end portions 332 are respectively used to abut against two sides of the second plate portion 352 of the base 35, in the present embodiment, abut against positions of the second plate portion 352 which are positioned behind the side fins 356 and are respectively positioned at two sides of the fin portion 36. The pivoting hole 123a may be formed by a hole provided to the first side wall 302 of the lower the shell 30a and a hole provided to the second side wall 303 of the upper the shell 30b which are communicated with each other.

Referring to FIG. 7 and FIG. 8, when the heat sink 31 is received in the shell 30, because of a relationship that two sides of the bottom of the base 35 are elastically supported upwardly by the two supporting elastic members 34 respectively, the actuating member 33 is normally in the first state and is capable of being displaced to the second state when the actuating member 33 is subjected to a force, when in the first state, the actuating member 33 entirely is subjected to a relationship that the actuating member 33 is supported upwardly by the supporting elastic member 34 via the base 35 due to the second end portion 332, the first end portion 331 is in a state that the first end portion 331 enters into the inserting passageway 115, but when in the second state, the second end portion 332 of the actuating member 33 acts on the heat sink 31 to make the base 35 of the heat sink 31 enter into the inserting passageway 115.

More specifically, referring to FIG. 7, when the pluggable module 4 does not insert into the inserting passageway 115, the actuating member 33 is in the first state, at this time, the first end portion 331 of the actuating member 33 enters into the inserting passageway 115, and the heat sink 31 is supported upwardly by the supporting elastic members 34 so that the thermal engaging portion 353 does not downwardly enter into the inserting passageway 115. It is noted that, in other implementing manners, when the actuating member 33 is in the first state, a height of the heat sink 31 also may be a height that the thermal engaging portion 353 enters into the inserting passageway 115 but does not contact the pluggable module 4, so before the pluggable module 4 pushes and moves the actuating member 33, the thermal engaging portion 353 at the bottom of the heat sink 31 and an upper surface of the pluggable module 4 have a gap therebetween.

Referring to FIG. 8, when the pluggable module 4 inserts into the inserting passageway 115 of the guide shielding cage 1 from front to rear via the insertion opening115a, the pluggable module 4 provides an external force which rearwardly and upwardly pushes the two first end portions 331 of the actuating member 33, and pushes and moves the actuating member 33 to gradually rotate from the first state to the second state, at this time, actuate the two first end portions 331 of the actuating member 33 to upwardly leave the inserting passageway 115, and actuate the two second end portions 332 to downwardly displace and apply a force to press down the second plate portion 352 of the plate portion 35a of the base 35, downwardly compress the supporting elastic member 34 via the base 35 (at this time, the second end portion 332 is in a direction which is substantially parallel to the second plate portion 352 and the second end portion 332 is close to the second plate portion 352), move the heat sink 31 downwardly to make the thermal engaging portion 353 downwardly pass through the window 111a, enter into the inserting passageway 115 and contact the surface of the pluggable module 4, so that an effect to help heat dissipating by contacting between the thermal engaging portion 353 and the pluggable module 4 is attained.

In conclusion, in the connector assembly 100 of the present disclosure, by adjustment of the provided position of the actuating member 33, the components of the heat sink module 3 are more simplified, in addition, by that the shaft portion 330 of the actuating member 33 sits on the top surface of the base 35 or is at least partially positioned outside the air passageways 363, blocking the air passageways 363 of the fin portion 36 is reduced, in turn influence on heat dissipating of the air flows of the air passageways 363 due to blocking of the shaft portion 330 is lowered, so the object of the present disclosure can be indeed attained.

However, the above description is only for the embodiment of the present disclosure, and it is not intended to limit the implementing scope of the present disclosure, and the simple equivalent changes and modifications made according to the claims and the contents of the specification are still included in the scope of the present disclosure.

What is claimed is:

1. A connector assembly, comprising:
a guide shielding cage having an inserting passageway; and
a heat sink module provided to the guide shielding cage and comprising:
a heat sink which has a base and a fin portion provided to the base; and
an actuating member which has a shaft portion and a lever connecting the shaft portion, the lever having a first end portion and a second end portion which are connected with each other, the shaft portion passing through the heat sink and siting on a top surface of the base;
wherein the actuating member is normally in a first state and is capable of being displaced to a second state when the actuating member is subjected to a force; when the actuating member is in the first state, the first end portion enters into the inserting passageway; when the actuating member is in the second state, the second end portion of the actuating member acts on the heat sink to make the base of the heat sink enter into the inserting passageway.

2. The connector assembly of claim 1, wherein
the heat sink module further comprises a supporting elastic member, the supporting elastic member elastically supports the heat sink to make the actuating member normally in the first state.

3. The connector assembly of claim 1, wherein
the base is formed with a first recessed groove, the fin portion is formed with a second recessed groove, the first recessed groove and the second recessed groove cooperate with each other to define a shaft hole which allows the shaft portion of the actuating member to pass therethrough, the shaft portion sits on a surface of the first recessed groove.

4. The connector assembly of claim 1, wherein
the base comprises a plate portion and a thermal engaging portion, the thermal engaging portion is positioned to a bottom surface of the plate portion of the base, when the actuating member is in the second state, the second end portion presses down the plate portion.

5. The connector assembly of claim 4, wherein
the base further comprises two side fins which extend upwardly from the plate portion, the fin portion is positioned between the two side fins.

6. The connector assembly of claim 5, wherein
when the actuating member is in the second state, the second end portion is in a direction which is substantially parallel to the plate portion and the second end portion is close to the plate portion.

7. The connector assembly of claim 2, wherein
the heat sink module further comprises a shell, the heat sink is received in the shell, the actuating member is provided to the shell.

8. The connector assembly of claim 7, wherein
the shell comprises a lower shell and an upper shell which are engaged with each other, the supporting elastic member is formed to the lower shell of the shell.

9. The connector assembly of claim 8, wherein
the lower shell of the shell is formed with a frame mouth, the two supporting elastic members are integrally constructed to the lower shell in a manner that the two supporting elastic members are respectively positioned to two sides of the frame mouth of the lower shell.

10. The connector assembly of claim 4, wherein
the thermal engaging portion of the heat sink comprises a thermal conductive pad.

11. A connector assembly, comprising:
a guide shielding cage having an inserting passageway; and
a heat sink module provided to the guide shielding cage and comprising:
a heat sink which has a fin portion, the fin portion being formed with an air passageway; and
an actuating member which has a shaft portion and a lever connecting the shaft portion, the lever having a first end portion and a second end portion, the shaft portion passing through the heat sink and being at least partially positioned outside the air passageway;
wherein the actuating member is normally in a first state and is capable of being displaced to a second state when the actuating member is subjected to a force; when the actuating member is in the first state, the first end portion enters into the inserting passageway; when the actuating member is in the second state, the second end portion of the actuating member acts on the heat sink to make the heat sink enter into the inserting passageway.

12. The connector assembly of claim 11, wherein
the heat sink module further comprises a supporting elastic member, the supporting elastic member elastically supports the heat sink to make the actuating member normally in the first state.

13. The connector assembly of claim 11, wherein
the heat sink further has a base, the base is formed with a first recessed groove, the fin portion is formed with a second recessed groove, the first recessed groove and the second recessed groove cooperate with each other to define a shaft hole which allows the shaft portion of the actuating member to pass therethrough, the shaft portion is at least partially positioned outside the air passageway by that the shaft portion is positioned in the first recessed groove.

14. The connector assembly of claim 13, wherein
the base comprises a plate portion and a thermal engaging portion, the thermal engaging portion is positioned to a bottom surface of the plate portion of the base, when the actuating member is in the second state, the second end portion presses down the plate portion.

15. The connector assembly of claim 14, wherein
the base further comprises two side fins which extend upwardly from the plate portion, the fin portion is positioned between the two side fins.

16. The connector assembly of claim 15, wherein
when the actuating member is in the second state, the second end portion is in a direction which is substantially parallel to the plate portion and the second end portion is close to the plate portion.

17. The connector assembly of claim 12, wherein
the heat sink module further comprises a shell, the heat sink is received in the shell, the actuating member is provided to the shell.

18. The connector assembly of claim 17, wherein
the shell comprises a lower shell and an upper shell which are engaged with each other, the supporting elastic member is formed to the lower shell of the shell.

19. The connector assembly of claim 18, wherein
the lower shell of the shell is formed with a frame mouth, the two supporting elastic members are integrally constructed to the lower shell in a manner that the two supporting elastic members are respectively positioned to two sides of the frame mouth of the lower shell.

20. The connector assembly of claim 14, wherein
the thermal engaging portion of the heat sink comprises a thermal conductive pad.
